(19) United States
(12) Patent Application Publication
(10) Pub. No.: US 2007/0102729 A1
(43) Pub. Date: May 10, 2007

(54) Method and system for providing a heterojunction bipolar transistor having SiGe extensions

(76) Inventors: Darwin Gene Enicks, Colorado Springs, CO (US); John Taylor Chaffee, Colorado Springs, CO (US); Damian Carver, Colorado Springs, CO (US)

Correspondence Address: SAWYER LAW GROUP LLP, P O BOX 51418, PALO ALTO, CA, 94303, US

(21) Appl. No.: 11/267,474

(22) Filed: Nov. 4, 2005

(51) Int. Cl. H01L 31/109; H01L 21/331

(52) U.S. Cl. 257/197; 257/198; 438/235; 438/309

(57) ABSTRACT

A method and system for providing a bipolar transistor is described. The method and system include providing a compound base region including includes a compound box extension, providing an emitter region, and providing a collector region. The emitter region is coupled with the base region. The SiGe base region is coupled with the collector region and includes a SiGe box extension. The box extension resides substantially between the emitter and the heterogeneous base region.

### CROSS-REFERENCE TO RELATED APPLICATIONS

The present application is related to co-pending U.S. Patent Application Serial No. ______ entitled Method and System for Controlled Oxygen Incorporation in Compound Semiconductor Films for Device Performance Enhancement (3506P) filed on even date herewith and assigned to the assignee of the present application, and U.S. Patent Application Serial No. ______ entitled Bandgap Engineered Mono-Crystalline Silicon Cap Layers for SiGe HBT Performance Enhancement (3508P) filed on even date herewith and assigned to the assignee of the present application, and U.S. Patent Application Serial No. ______ entitled Bandgap and Recombination Engineered Emitter Layers for SiGe HBT Performance Optimization (3509P) filed on even date herewith and assigned to the assignee of the present application.

### FIELD OF THE INVENTION

The present invention relates to semiconductor processing, and more particularly to a method and system for dopant profiles providing improved performance of heterostructure devices such as heterojunction bipolar transistor (HBT) devices.

### BACKGROUND OF THE INVENTION

The conventional SiGe HBT has significant advantages over a silicon bipolar junction transistor (BJT) in gain, frequency response, noise parameters and retaining the ability to be readily integrated with CMOS at relatively low cost. Cutoff frequencies (Fₜ) of conventional SiGe HBT devices have been reported to exceed 300 GHz, which is favorable as compared to GaAs devices. Moreover, GaAs devices are relatively high in cost and cannot achieve the level of integration of technologies such as BiCMOS. The silicon compatible conventional SiGe HBT provides a low cost, high speed, low power solution that is quickly replacing other compound semiconductor devices.

FIG. 1 depicts the filmstack of a conventional heterojunction bipolar transistor (HBT) device 10 formed on a substrate 11. The conventional HBT device 10 includes a conventional collector region 12, a conventional compound base region 16, and a conventional emitter region 20. The conventional HBT device 10 may also include a conventional spacer (or seed) layer 14 and a conventional capping layer 18.

In a conventional HBT 10, the conventional spacer layer 14 is typically an elemental semiconductor, such as silicon. The conventional base region 16 is typically formed from a compound semiconductor, such as SiGe or SiGeC (SiGe doped with C) (collectively hereinafter SiGe/SiGeC). The conventional capping layer 18 is typically an elemental semiconductor, such as silicon. The conventional emitter layer 18 is typically polysilicon. One of ordinary in the art will recognize that other materials of the poly-, mono-, and/or amorphous construction will also work well for the emitter layer, such as poly-SiGe or amorphous silicon, to name a few.

The conventional HBT 10 may either be npn or pnp, depending on the device application. For instance, with an npn SiGe/SiGeC HBT, the conventional collector region 12 is doped with n-type dopants such as arsenic and/or phosphorus. The process dopant gases are usually arsine (AsH₃) and/or phosphine (PH₃) respectively. The collector region 12 may be formed in an epitaxial reactor at temperatures in the 900° C. to 1000° C. range. The collector region 12 may be doped in-situ during epitaxial film growth or by ion implantation or diffusion sources after film growth. Silane (SiH₄) is the typical silicon source gas. Temperatures below 900° C. and greater than 1000° C. may also be used. The conventional spacer 14, SiGe/SiGeC base layer 16, and the conventional cap layer 18 are typically formed together in the same process. The silicon source gas for all layers is typically silane (SiH₄). Growth temperatures usually range between 500° C. and 900° C.; growth pressures typically ranges between one and one hundred torr. The conventional spacer region 14 may be either undoped or doped n-type with either arsenic or phosphorus, by the use of arsine (AsH₃) and/or phosphine (PH₃) gases, respectively. The conventional SiGe and/or SiGeC layer is typically grown at temperatures ranging from 600° C. to 700° C., although temperatures less than 600° C. and greater than 700° C. may be utilized. Germane (GeH₄) is the typical source of germanium. The epitaxial SiGe and/or SiGeC growth usually takes place in an LBCVD (low pressure chemical vapor deposition) reactor. However, other methods including UHVCVD (ultrahigh vacuum CVD) and MBE (molecular beam epitaxy) may be utilized. The conventional capping layer 18 is typically grown at temperatures in the range of 700° C. to 900° C. and may be either doped or undoped. If doped, the n-type species is usually arsenic and/or phosphorus, with arsine (AsH₃) and/or phosphine (PH₃) respectively.

Use of the conventional SiGe/SiGeC layer for the conventional compound base region 16 results in a base-emitter heterojunction. Because SiGe has a lower energy bandgap than silicon, the base-emitter heterojunction results in a bandgap offset between the conventional compound base 16 and the conventional emitter 20. This bandgap reduction is translated into both the conduction and valence bands in such a way as to improve device performance.

FIG. 2 depicts the energy band structure 30 of an npn HBT device in a forward active mode, in which the base-collector junction is reverse biased and the base-emitter junction is forward biased. The lowering of the conduction band lowers the barrier against electron injection from emitter to base and thereby results in an increase in current density for a give base-emitter voltage bias. Elevating the valence band energy provides a barrier against hole-diffusion from the conventional compound base 16 to the conventional emitter 20. An increase in electron injection, combined with reduced hole current provides higher gains and higher Fₜ than can be realized by a similarly doped and structured silicon BJT. Thus, a silicon BJT with the same dimensions, layer thickness, and doping levels in collector, base, and emitter as a conventional SiGe/SiGe HBT regions will not operate as efficiently as the conventional SiGe/SiGeC HBT.

Therefore, advantages of SiGe/SiGeC may be realized by a bandgap reduction that creates an energy band offset at the base-emitter SiGe heterojunction of the HBT. As a result, increased current density and current gain for a given base-emitter bias may be achieved. The bandgap offset is typically generated by the incorporation of germanium (Ge) with the silicon lattice. Stated differently, a diamond crystalline structure including a blend of silicon and germanium results in a bandgap that is less than that of silicon only. Furthermore, a lower resistivity is possible with addition of Ge to a Si lattice. In addition, boron diffusivity is greatly reduced with the addition of Ge. A silicon interstitial and boron pairing primarily enhance boron diffusivity. However, Ge increases the vacancy population, or diminishes the interstitial population, which acts to reduce boron diffusion. Therefore, advantages of SiGe may include:
1. Bandgap engineering flexibility
2. Reduction in dopant diffusivity, esp. boron
3. Ease of integration with standard silicon technologies

FIG. 3 depicts a film stack 40 of a conventional SiGe/SiGeC HBT device having a trapezoidal silicon germanium region with a ramped profile on the side of the base-emitter heterojunction. The bandgap offset, defined where the metallurgical junction aligns with the base-emitter heterojunction (ΔEG(0)), and/or the bandgap grading across the neutral base region (ΔEG(grade)) are key components to the HBT device performance. Each of these bandgap effects is induced by the incorporation of Ge into the silicon lattice. Current density (J_{c}) is exponentially dependent on the bandgap offset at the base-emitter heterojunction (ΔEG(0)) and linearly dependent on the Ge grade or (ΔEG(grade)).
J_{c}αexp[ΔEG(0)]*(ΔEG(grade))
The higher current densities and lower base resistance values allow improved unity gain cutoff frequencies and maximum oscillation frequencies than comparable silicon BJTs, and are comparable to other compound devices such as GaAs.

The base-emitter bandgap offset, (ΔEG(0)), is determined by the relative position of the metallurgical junction with respect to the germanium profile near the base-emitter heterojunction as depicted in FIG. 3. The metallurgical junction is approximately located by the pn junction formed inside the silicon germanium layer, where the n-type dopants from the emitter and/or cap layer intersect the p-type dopant from the conventional SiGe/SiGeC base layer 16. This also defines the front edge, or base-emitter edge, of the neutral base region; this is the point where x=0. Stated differently, the neutral base region of the conventional compound base layer 16 is located to the right of x=0 in FIG. 3. The base-emitter edge for the conventional compound base 16 is at x=0. The intersection is typically formed during thermal anneals, which occur after the formation or growth of the film stacks making up the conventional HBT 10. FIG. 3 depicts a trapezoidal silicon germanium region with a ramped profile on the side of the base-emitter heterojunction. One of ordinary skill in the art will, however, recognize that other profiles are also possible. These profiles include, but are not limited to box profiles, triangular profiles, and profiles that include a curvature of shape.

Variations in processing, such as thermal depositions and thermal anneals that occur either during or following the NPN HBT 10 filmstack formation, can cause the metallurgical junction to vary its position relative to the base-emitter heterojunction and relative to the dopant concentrations at their point of intersection. For instance, as depicted in FIG. 3, sliding the metallurgical junction backwards and forwards (to simulate thermal processing effects) will result in an up and down movement of the base-emitter bandgap offset, ΔEG(0). In addition, the approximate physical location of the metallurgical junction may be defined as the point at which both dopant profiles are equal. Therefore, variations to the magnitudes of dopant concentration at this point also may have implications to device characteristics. Such device parameters related to depletion region formation will be impacted to include emitter-base junction capacitance, Cⱼₑ. The variation of ΔEG(0) will equate to variation in electron injection from emitter to base, and hence variation in current density, J_{c}, which will cause variations in electron-current dependent device parameters such as current gain (β), unity gain cutoff frequency (Fₜ), and maximum oscillation frequency (Fₘₐₓ), and other parameters. One of ordinary skill in the art will recognize that even though FIG. 3 depicts a trapezoidal profile; other profiles are still susceptible to this type of variation. These profiles include, but are not limited to box profiles, triangular profiles, and profiles that include a curvature of shape.

In order to fabricate the conventional HBT device 10, the SiGe or SiGeC is grown on the conventional spacer layer 14. The SiGe/SiGeC layer of the conventional base region 16 is typically pseudomorphically grown to match the lattice of the silicon in the conventional spacer 14. Consequently, the SiGe/SiGeC is in a compressively strained state. The conventional capping layer 18 is grown on the SiGe/SiGeC. The conventional capping layer 18 helps to maintain the SiGe/SiGeC for the conventional base 16 in a strained state during thermal treatments to help reduce or prevent crystalline defects.

Portions of the conventional HBT device 10 are also doped during fabrication. The conventional capping layer 18 may be doped as discussed above. The addition of dopants such as C (e.g. in SiGeC) or O (oxygen) may further reduce the diffusion rate of boron in the conventional base region 16 and allow for engineering of minority carrier lifetimes and/or recombination current for added design flexibility to achieve critical performance objectives, such as, for instance current gains and breakdown voltages. The conventional emitter 20 and the conventional collector 12 are also typically doped to form an NPN or a PNP conventional HBT 10.

A base-emitter metallurgical junction results from fabrication of the conventional HBT device 10. The site of the base-emitter metallurgical junction can be approximated by the location at which the base dopant and emitter dopant are equal. The base-emitter metallurgical junction is desired to be within the conventional base region 16 in order to take advantage of the bandgap offset due to the heterojunction. The BE bandgap offset is a significant component in determining the collector current, the base current, the current gain, and Fₜ and Fₘₐₓ figures a conventional SiBe/SiBeCHBT device 10.

FIG. 4 is a graph 50 depicting the dopant profiles for the conventional HBT 10. Thus, the conventional graph 50 includes profiles illustrating the positions of the As dopant 52 for the conventional emitter region 20, Ge dopant 56 for the SiGe/SiGeC layer of the conventional base region 16, and boron dopant 54 for the conventional base region. Note that the specific shapes and locations of the profiles 52, 54, and 56 for explanatory purposes and not necessarily meant to represent a particular real-world device. The graph 50 is a conventional scissor profile, named so because of the shapes of the profiles 52 and 54 where the profiles 52 and 54 meet. The metallurgical junction 60 is also shown in the graph 50. The bandgap offset is denoted as ΔEG. At the metallurgical junction the bandgap offset is ΔEG (x=0) because x=0 is defined by the metallurgical junction.

Although the conventional HBT device 10 functions, one of ordinary skill in the art will readily recognize that the conventional HBT device 10 may be subject to significant variations in parameters such as base and collector currents as well as current gain. In particular, ΔEG (x=0) occurs in the ramp section, 56A, of the Ge profile 56. Consequently, the concentration of Ge dopant may vary as the position of the metallurgical junction (x=0) changes. The position of the metallurgical junction may change because of variations in thermal cycles in downstream processing as well as variations in the process of forming the metallurgical junction. Consequently, the parameters such as base current, collector current, and current gain for the conventional HBT device 10 may be unstable.

Accordingly, what is needed is a method and system for improving manufacturability and performance of the conventional HBT device 10. The present invention addresses such a need.

### BRIEF SUMMARY OF THE INVENTION

The present invention provides a method and system for providing a bipolar transistor. The method and system comprise providing a compound base region, providing an emitter region and providing a collector region. The emitter region is coupled with the base region. The compound base region is coupled with the collector region and includes a compound box extension. The compound box extension resides substantially between the emitter and the compound base region.

According to the method and system disclosed herein, the present invention allows diffusion and strain limiting impurities such as oxygen and/or carbon to be provided in a controlled manner that allows for improved performance of the bipolar transistor.

### BRIEF DESCRIPTION OF SEVERAL VIEWS OF THE DRAWINGS

FIG. 1 is a diagram of a conventional heterojunction bipolar transistor device.

FIG. 2 depicts the energy band structure of a conventional npn HBT device in a forward active mode. %

FIG. 3 depicts a film stack of conventional SiGe/SiGeC HBT device having a trapezoidal silicon germanium region with a ramped profile on the side of the base-emitter heterojunction.

FIG. 4 depicts the dopant profile for a conventional heterojunction bipolar transistor device.

FIG. 5 is a diagram of a film stack of one embodiment of a heterojunction bipolar transistor device in accordance with the present invention.

FIG. 6 depicts dopant profiles for one embodiment of a heterojunction bipolar transistor device in accordance with the present invention.

FIG. 7 depicts dopant profiles for one embodiment of a heterojunction bipolar transistor device in accordance with the present invention.

FIG. 8 is a flow chart depicting one embodiment of a method in accordance with the present invention for providing a heterogeneous bipolar transistor device.

### DETAILED DESCRIPTION OF THE INVENTION

The present invention relates to semiconductor devices. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

The present invention provides a method and system for providing a bipolar transistor. The method and system include providing a compound base region including includes a compound box extension, providing an emitter region, and providing a collector region. The emitter region is coupled with the base region. The SiGe base region is coupled with the collector region and includes a SiGe box extension. The box extension resides substantially between the emitter and the heterogeneous base region.

The present invention will be described in terms of a particular HBT device. However, one of ordinary skill in the art will readily recognize that the method and system may be applicable to other device(s) having other, additional, and/or different components, dopants, and/or positions not inconsistent with the present invention. The present invention is also described in the context of particular methods. One of ordinary skill in the art will, however, recognize that the method could have other and/or additional steps. Moreover, although the methods are described in the context of providing a single HBT device, one of ordinary skill in the art will readily recognize that multiple devices may be provided in parallel and/or series. The present invention is also described in the context of particular dopant profiles. However, one of ordinary skill in the art will readily recognize that the shapes, locations, and other features of the profiles may vary. The method is also described in the context of particular methods. However, one of ordinary skill in the art will recognize that the methods may omit or combine steps for ease of explanation. In addition, many industries allied with the semiconductor industry could make use of the hetero extension technique. For example, a thin-film head (TFH) process in the data storage industry or an active matrix liquid crystal display (AMLCD) in the flat panel display industry, or in manufacturing of laser emitting diodes (LED), and the micro-electromechanical (MEM) industry could readily make use of the processes and techniques described herein. Similarly, the method and system may be used in vertical thin film transistor (VTFTs) and strained field effect transistor (FET) devices such as strained Si, strained SiGe, and strained Ge channel devices. The method and system may also be used with other strained layers in other compounds. Examples of such devices may include but are not limited to devices using GaAs, InP, and AlGaAs. One of ordinary skill in the art will readily recognize that the present invention may be used in conjunction with such devices. Thus, the terms used herein, including but not limited to the term semiconductor, may thus include the aforementioned and related industries.

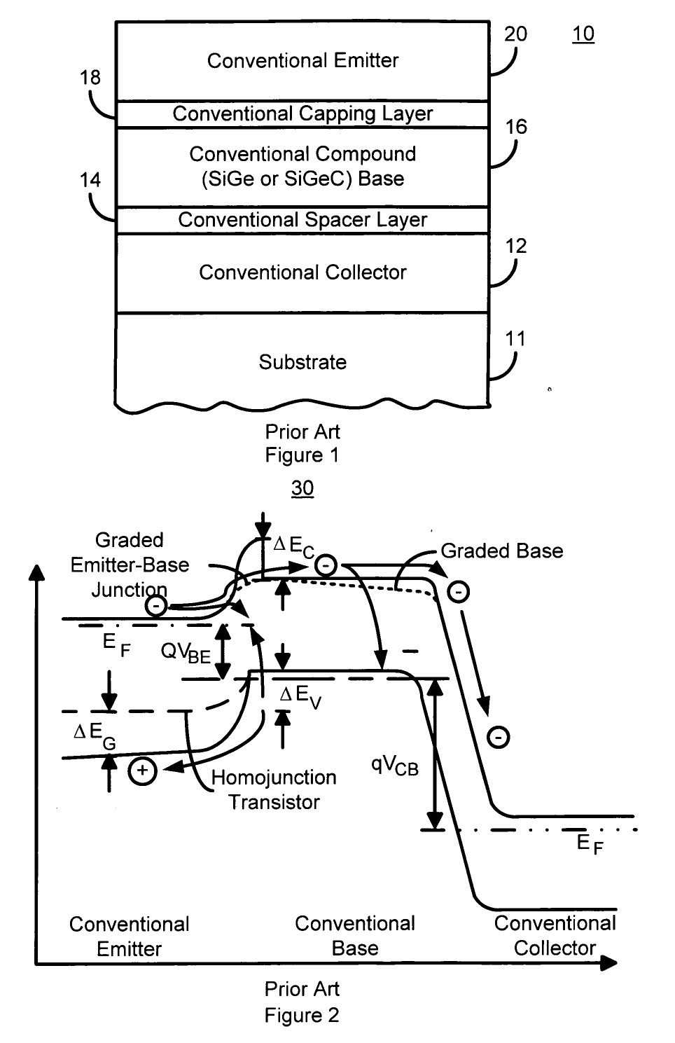

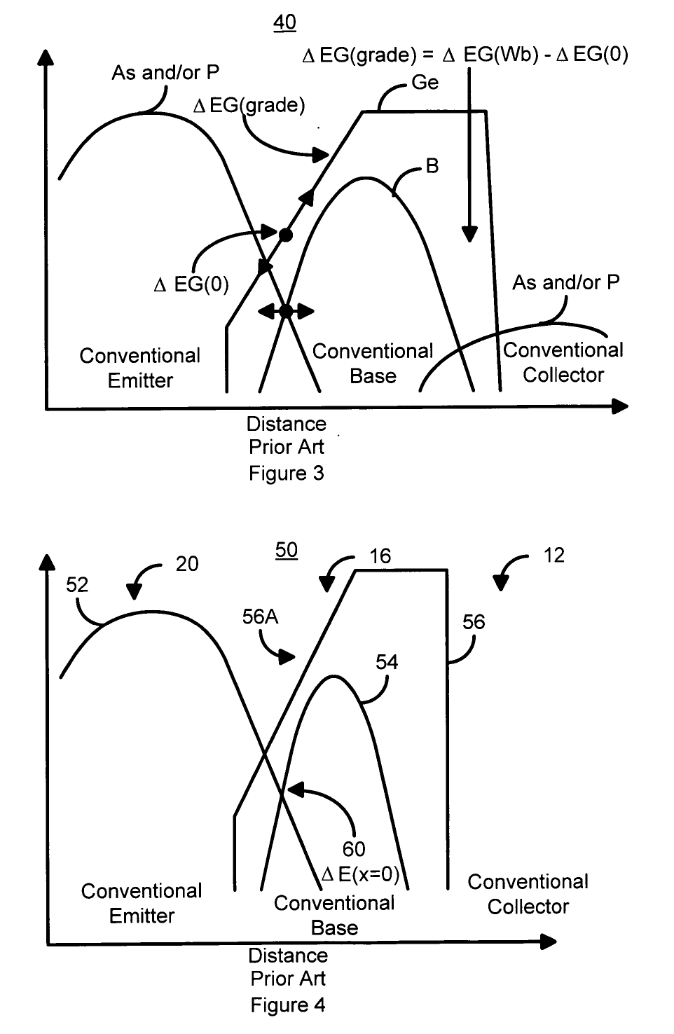

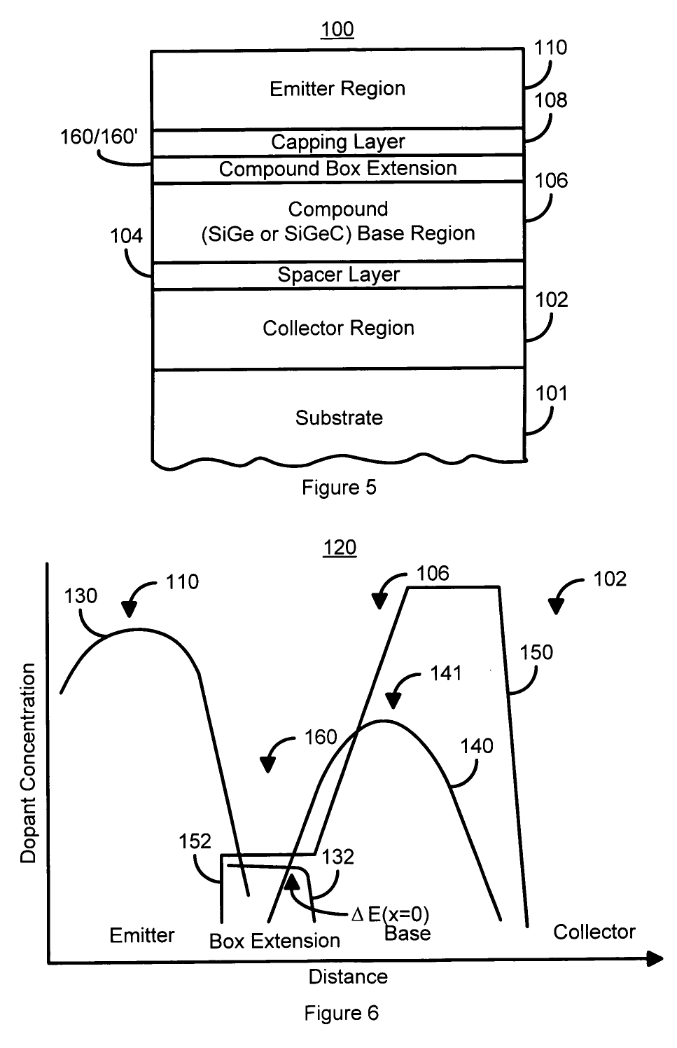

FIG. 5 is a diagram of one embodiment of a filmstack of a heterojunction bipolar transistor device 100 in accordance with the present invention. The HBT device 100 is formed on a substrate 101. The HBT device 100 includes a collector region 102, a compound base region 106 having a box extension, described below, and an emitter region 110. The HBT device 100 may also include a spacer layer 104 and a capping layer 108. The spacer layer 104 and the capping layer 108 are analogous to the conventional spacer layer 14 and the conventional capping layer 18 described in FIG. 1.

Referring back to FIG. 5, the spacer layer 104 is typically undoped silicon. The compound base region 106 is typically formed from a layer that is typically SiGe or SiGeC. Consequently, a base-emitter heterojunction and a base-emitter metallurgical junction are present in the HBT 100. The SiGe/SiGeC for the base layer 106 is preferably pseudomorphically grown on the spacer layer 104 to match the lattice of the silicon in the spacer layer 104. Consequently, the SiGe/SiGeC is in a compressively strained state. The capping layer 108 is grown on the SiGe/SiGeC and helps to maintain the SiGe/SiGeC for the conventional base 16 in a strained state during subsequent thermal treatments to help reduce or prevent crystalline defects. The base region 106 formed in the SiGe/SiGeC layer is doped, generally using boron to provide a p-type base. The Ge in the SiGe/SiGeC of the base region 106 results in a lower diffusion rate for the boron dopant. The addition of other dopants such as C (e.g. in SiGeC) or O may further reduce the diffusion rate of boron in the base region 106. Although the capping layer 108 is typically undoped silicon, the capping layer 108 might be doped, for example using arsenic or phosphorus. The emitter 110 and the collector 102 are also typically doped to form an NPN or a PNP HBT 100.

As mentioned above, the compound base region 106 includes a box extension 160/160′ described in more detail below. For the HBT device 100, the box extension 160/160′ includes at least a Ge dopant, and may include other dopants. Consequently, The box extension 160/160′ will be termed a compound box extension. The compound box extension 160/160′ may enhance the thermal stability of the HBTO device 100, and may reduce the sensitivity of HBT 100 to variations in formation, may provide improved control over device parameters such as collector current, base current and current gain.

FIG. 6 is a graph 120 depicting one embodiment of dopant profiles in accordance with the present invention for one embodiment of the HBT device 100 in accordance with the present invention. The graph 120 depicts the compound box extension 160 among other features of the HBT device 100. The graph 120 is for an HBT device 100 having an n-type emitter formed using As as a dopant and a p-type base using B as a dopant. However, the same principles apply for other dopants including dopants having other types. Thus, the As profile (emitter dopant profile) 130 for the emitter 110, the B profile (base dopant profile) 140 for the compound base 106, and the Ge profile 150 for the SiGe/SiGeC are depicted. Also shown are the Ge extension 152 and an emitter extension 132 for the As dopant. The Ge profile 150 includes a peak within the neutral base region of the compound base 110.

The compound box extension 160 includes the extensions 152 and 132 for the Ge profile 150 of the SiGe/SiGeC and the As 130 for the emitter 130, respectively. In another embodiment, the B profile 140 may include a box extension (not shown) analogous to the extension 132 in lieu of the extension 132. The Ge extension 152 has a concentration that is relatively flat and has a value that is less than the peak concentration 141 of the profile 140 for the base dopant. In a preferred embodiment, the Ge extension 152 for the compound box extension 160 has a concentration of at least one percent and not more than twenty-five percent Ge. Also in a preferred embodiment, the Ge extension 152 has a length of 0.1 nm to fifteen nm. Although depicted with a particular Ge profile 150, the Ge extension 152 may be used with virtually any profile, including but not limited to grade, triangle, and trapezoid profiles of the Ge. In addition, the compound box extension 160 includes an n-type dopant, here As extension 132. The emitter extension 132 is also relatively flat and, in a preferred embodiment, has a concentration that is less than the maximum for the emitter dopant 130. In a preferred embodiment, the emitter extension 132 has a concentration of at least 5×10¹⁶ atoms/cm³ and not more than 5×10¹⁹ atoms/cm³. Furthermore, both the extensions 152 and 132 are both in the box extension 160. Stated differently, the extensions 152 and 132 overlap. In addition, the base dopant B 140 overlaps the emitter dopant at the emitter extension 132.

Because of the use of the compound box extension 160, including extensions 152 and 132, the HBT device 100 may have improved performance. In particular, the metallurgical junction, ΔE(x=0) is where the base dopant B 140 and the emitter dopant, the extension 132, cross. This metallurgical junction is within the compound region 152 of the compound box extension 160. Thus, the metallurgical junction occurs where the Ge concentration and the As concentration are relatively constant. Because the metallurgical junction occurs where the Ge concentration is substantially the same, the processing related variations in performance of the HBT device 100 are reduced. Stated differently, the variations in the exact position of the metallurgical junction may not significantly alter parameters of the HBT device 100. In addition, the compound box extension 160 may improve the thermal stability of the metallurgical junction. Consequently, parameters such as collector and base currents and current gain may be more closely controlled.

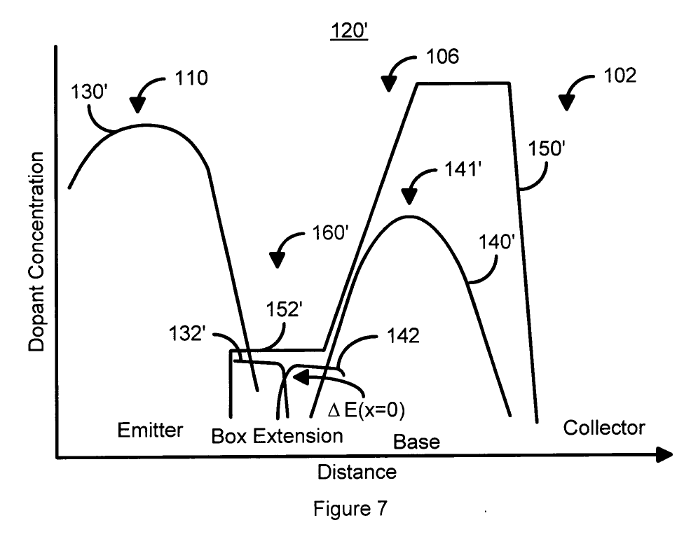

FIG. 7 depicts another graph 120′ of embodiment of dopant profiles in accordance with the present invention for another embodiment of the HBT device 100. The graph 120′ is analogous to the graph 120. Consequently, analogous components are labeled similarly. The graph 120′ is for an HBT device 100 having an n-type emitter formed using As as a dopant and a p-type base using B as a dopant. However, the same principles apply for other dopants including dopants having other types. Thus, the As profile 130′ for the emitter 110, the B profile 140′ for the base 106, and the Ge profile 150′ for the SiGe/SiGeC are depicted. Also shown is the box extension 160′ that includes the Ge extension 152′, optional emitter extension 132′ for the As dopant, and the base extension 142. The Ge profile 150′ includes a peak within the neutral base region of the compound base 110′.

The box extension 160′ includes the extensions 152′, 132′, and 142 for the Ge profile 150′ of the SiGe/SiGeC, the As profile 130′ for the emitter 110, and the B profile 140′ for the base 106, respectively. The Ge extension 152′ has a concentration that is relatively flat and has a value that is less than the peak concentration 141′ of the profile 140′ for the base dopant. In a preferred embodiment, the Ge extension 152′ for the box extension 160′ has a concentration of at least one percent and not more than twenty-five percent Ge. Also in a preferred embodiment, the Ge extension 152′ has a length of 0.1 nm to fifteen nm. Although depicted with a particular Ge profile 150′, the Ge extension 152′ may be used with virtually any profile, including but not limited to grade, triangle, and trapezoid profiles of the Ge. In addition, the box extension 160′ includes an n-type dopant as well as a p-type dopant, which are emitter extension 132′ and base extension 142, respectively. The emitter extension 132′ is relatively flat and, in a preferred embodiment, has a concentration that is less than the maximum for the emitter dopant 130′. In a preferred embodiment, the emitter extension 132′ has a concentration of at least 5×10¹⁶ atoms/cm³ and not more than 5×10¹⁹ atoms/cm³. The base extension 142′ is relatively flat and, in a preferred embodiment, has a concentration that is less than the maximum for the base dopant 140′. Furthermore, the extensions 132′, 142, and 152′ are in the box extension 160. Stated differently, the extensions 132, 142, and 152′ overlap.

Because of the use of the box extension 160′, including extensions 132′, 142 and 152′, the HBT device 100 may have improved performance. In particular, the metallurgical junction, ΔE(x=0) is approximately located in the region where the base dopant in the base extension 142 and the emitter dopant in the emitter extension 132′ cross. This metallurgical junction is substantially within the compound box region 152′ of the box extension 160′. Thus, the approximate “center” of the metallurgical junction occurs where the Ge concentration, the B concentration, and the As concentration are relatively equivalent. Because the metallurgical junction occurs where the Ge concentration is substantially the same, the processing related variations in performance of the HBT device 100′ are reduced. Stated differently, the variations in the exact position of the metallurgical junction may not significantly alter parameters of the HBT device 100′. In addition, the box extension 160′ may improve the thermal stability of the metallurgical junction. Consequently, parameters such as collector and base currents and current gain may be more closely controlled. Thus, the HBT device may have improved characteristics.

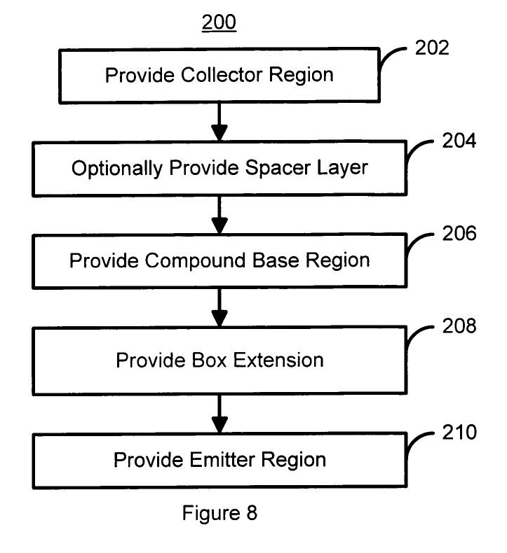

FIG. 8 is a flow chart depicting another embodiment of a method 200 in accordance with the present invention for providing a heterogeneous bipolar transistor device. The method 200 is described in the context of the HBT device 100. However, one of ordinary skill in the art will readily recognize that the method 200 could be used with other HBT devices in accordance with the present invention. One of ordinary skill in the art will also recognize that for ease of explanation, steps may be omitted, combined, or performed in a different order. A collector region 102 is provided, via step 202. Step 202 preferably includes doping the collector region 102 with the desired n-type or p-type dopant(s) depending on the transistor type, npn or pnp. In general, n-type dopants such as As or P are used, while boron is used as a p-type dopant. A SiGe spacer layer 104 may optionally be provided, via step 204. A compound base region 106 is provided, via step 206. The compound base region 106 is coupled with the collector region 102. In some embodiments, the compound base region 106 is provided such that a seed layer and the spacer layer 104 may reside between the compound base region 106 and the collector region 102. Step 206 may include growing a seed layer and the collector spacer layer 104 as well as the SiGe/SiGeC base layer 106. The compound base region 106 is preferably grown with the desired dopant(s), such as B added in situ. A compound box extension 160/160′ is provided, via step 208 in the same process chamber as 206 and immediately after 206. In addition, an emitter spacer layer and the capping layer 108 may be provided between the emitter 110 and the base 106 in the same process chamber immediately after the SiGe box extension 160/160′ is provided. The emitter 110 may be provided, via step 210.

The SiGe box extension 160/160′ is provided in step 208. Step 208 includes doping the SiGe box extension 160/160′ with some combination of dopants used for the SiGe/SiGeC base 106 and the emitter 110. In a preferred embodiment, this includes using some or all of the impurities C, 0, P, As, and B as dopants in some combination. In one embodiment, the stack comprised of layers 104, 106, and 108 may be grown using a chemical vapor deposition process with deposition temperatures ranging between 500° C. and 900° C. Arsine (AsH₃), Phosphine (PH₃), and Diobrane (B₂H₆) may be used as precursors for n and p type dopants. If C and/or O are used in growing this stack, then methyl silane (CH₃SiH₃) may be used s the carbon source and heliox or other gases containing oxygen may be used as the oxygen source. Some dopants in this stack may also be implanted. C or O may be used throughout the box extension or only part of the box extension 160.

Thus, using the method 200, the HBT device 100 may be formed. Thus, the method 200 may provide an HBT device that has reduced processing related variations, including improved the thermal stability of the metallurgical junction. This is due to the metallurgical emitter-base junction residing in a region of constant Ge concentration, resulting in better control over device parameters such as collector current and current gain.

A method and system for providing a heterojunction bipolar transistor has been disclosed. The present invention has been described in accordance with the embodiments shown, and one of ordinary skill in the art will readily recognize that there could be variations to the embodiments, and any variations would be within the spirit and scope of the present invention. Accordingly, many modifications may be made by one of ordinary skill in the art without departing from the spirit and scope of the appended claims.

We claim:

1. A semiconductor device comprising:
a compound region including a box extension and a first dopant of a first type;
a doped region including a second dopant type and coupled with the compound region, the second dopant having a second type different from the first type, the box extension residing substantially between the region and the compound region.

2. A bipolar transistor comprising:
a compound base region including a compound box extension;
an emitter region coupled with the compound base region, the compound box extension residing substantially between the emitter region and the compound base region; and
a collector region coupled with the compound base region.

3. The bipolar transistor of claim 2 wherein the compound box extension includes at least one of C, 0, P, As, or B.

4. The bipolar transistor of claim 3 wherein the compound box extension includes As or B.

5. The bipolar transistor of claim 2 further comprising:
a first additional dopant residing in at least first portion of the compound box extension and a second additional dopant residing in at least a second portion of the compound box extension, the first additional dopant having a first type, the second additional dopant having a second type different from the first type.

6. The bipolar transistor of claim 5 wherein the first additional dopant includes As and the second additional dopant includes B.

7. The bipolar transistor of claim 2 wherein the compound box extension has a length of at least 0.1 nm and not more than 15 nm.

8. The bipolar transistor of claim 2 wherein the compound base includes a neutral base region and a graded profile having a maximum base Ge concentration within the neutral base region, the compound box extension extending from the graded profile and having a maximum box Ge concentration, and wherein the maximum box Ge concentration in the compound box extension is less than the maximum base Ge concentration.

9. The bipolar transistor of claim 2 wherein the compound base includes a neutral base region and a triangular Ge profile having a maximum base Ge concentration within the neutral base region, a compound box extension extending from the triangular Ge profile and having a maximum box Ge concentration, and wherein the maximum Ge box concentration is less than the maximum Ge base concentration in the neutral base.

10. The bipolar transistor of claim 2 wherein the compound base includes neutral base region and a trapezoidal Ge profile having a maximum Ge base concentration within the neutral base region, a compound box extension extending from the trapezoidal Ge profile and having a maximum Ge box concentration, and wherein the maximum Ge box concentration is less than the maximum Ge base concentration.

11. The bipolar transistor of claim 2 wherein the compound base region further includes C.

12. The bipolar transistor of claim 2 wherein the compound base is a SiGe base and wherein the compound box extension is a SiGe box extension.

13. A bipolar transistor comprising:
a SiGe base region having an emitter-base side and including a SiGe box extension on the emitter-base side;
an emitter region coupled with the SiGe base region, the SiGe box extension residing substantially between the emitter region and the SiGe base region; and
a collector region coupled with the SiGe base region.

14. A semiconductor device comprising:
at least one bipolar transistor, each of the at least one bipolar transistor including a compound base region including a compound box extension, an emitter region coupled with the compound base region, and a collector region coupled with the compound base region, the compound box extension residing substantially between the emitter region and the compound base region.

15. A method for providing a semiconductor device comprising:
providing a compound region including a first dopant of a first type;
providing a box extension within the compound region; and
providing a doped region including a second dopant type and coupled with the compound region, the second dopant having a second type different from the first type, the box extension residing substantially between the region and the compound region.

16. A method for providing a bipolar transistor comprising
providing a collector region;
providing a compound base region coupled with the collector region;
providing a compound box extension within the compound base region;
providing an emitter region coupled with the compound base region, the compound box extension residing substantially between the emitter and the compound base region.

17. The method of claim 16 wherein the compound box extension includes at least one of C, 0, P, As, or B.

18. The method of claim 17 wherein the compound box extension includes As or B.

19. The method of claim 16 further comprising:
a first additional dopant residing in at least first portion of the compound box extension and a second additional dopant residing in at least a second portion of the compound box extension, the first additional dopant having a first type, the second additional dopant having a second type different from the first type.

20. The method of claim 19 wherein the first additional dopant includes As and the second additional dopant includes B.

21. The method of claim 16 wherein the compound box extension has a length of at least 0.1 nm and not more than 15 nm.

22. The method of claim 16 wherein the compound base includes a neutral base region and a graded profile having a maximum base Ge concentration within the neutral base region, the compound box extension extending from the graded profile and having a maximum box Ge concentration, and wherein the maximum box Ge concentration in the compound box extension is less than the maximum base Ge concentration.

23. The method of claim 16 wherein the compound base includes a neutral base region and a triangular Ge profile having a maximum base Ge concentration within the neutral base region, a compound box extension extending from the triangular Ge profile and having a maximum box Ge concentration, and wherein the maximum Ge box concentration is less than the maximum Ge base concentration in the neutral base.

24. The method of claim 16 wherein the compound base includes neutral base region and a trapezoidal Ge profile having a maximum Ge base concentration within the neutral base region, a compound box extension extending from the trapezoidal Ge profile and having a maximum Ge box concentration, and wherein the maximum Ge box concentration is less than the maximum Ge base concentration.

25. The method of claim 16 wherein the compound base region further includes C.

26. The method of claim 16 wherein the compound base is a SiGe base and wherein the compound box extension is a SiGe box extension.

27. A method for providing bipolar transistor comprising:
providing a SiGe base region having an emitter-base side;
providing a SiGe box extension within the SiGe base region and residing on the emitter-base side of the SiGe base region;
providing an emitter region coupled with the SiGe base region, the SiGe box extension residing substantially between the emitter region and the SiGe base region; and
providing a collector region coupled with the SiGe base region.

28. A method for providing semiconductor device comprising:
providing at least one bipolar transistor, each of the at least one bipolar transistor including a compound base region including a compound box extension, an emitter region coupled with the compound base region, and a collector region coupled with the compound base region, the compound box extension residing substantially between the emitter region and the compound base region.
